(19) United States
(12) Patent Application Publication
(10) Pub. No.: US 2004/0253811 A1
(43) Pub. Date: Dec. 16, 2004

(54) Method for fabricating semiconductor device

(76) Inventors: Sung-Kwon Lee, Ichon-shi (KR); Min-Suk Lee, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/750,001

(22) Filed: Dec. 30, 2003

(30) Foreign Application Priority Data
Jun. 10, 2003 (KR) 2003-37111

(51) Int. Cl. H01L 21/4763

(52) U.S. Cl. 438/633

(57) ABSTRACT

A method for fabricating a semiconductor device capable of preventing an electric short circuit between a storage node contact plug and a conductive pattern by forming an attack barrier layer or use of an insulation layer having a flow-fill property. The attack barrier layer for preventing the electric short circuit is formed by employing two methods. First, the attack barrier layer is formed on an entire surface of a structure containing the plugs after the CMP process and the cleaning process. Second, the attack barrier layer is formed on a structure including a storage node contact hole such that the attack barrier layer fills the lost portion of the insulating material-based layer. Also, instead of using the attack barrier layer, the insulation layer having a flow-fill property is deposited after the cleaning process.

### FIELD OF THE INVENTION

The present invention relates to a method for fabricating a semiconductor device; and, more particularly, to a method for fabricating a semiconductor device including conductive patterns with an etch stop layer having a multi-layered insulation structure formed at sidewalls of the conductive patterns so that an electric short circuit between a plug and the conductive pattern can be blocked.

### DESCRIPTION OF RELATED ARTS

As an integration level of a semiconductor device increases, the thickness of an etch target layer also increases. Thus, a burden on an etching process has been extensively augmented.

For instance, in a dynamic random access memory (DRAM) device, a self-aligned contact (SAC) etching process is adopted for a cell contact process and a capacitor contact formation process. At this time, this SAC etching process is capable of preventing a gate electrode or a bit line from being attacked. Also, in order to obtain a characteristic SAC etch profile, a nitride-based etch stop layer having an etch selectivity value different from that of an oxide-based inter-layer insulation layer is formed at sidewalls and an upper surface of a conductive pattern, e.g., a gate electrode, a bit line and so on. The etch stop layer formed on the upper surface of the conductive pattern is almost removed and remains as a spacer during an etching process for forming a typical contact formation.

The increased thickness of the etch stop layer enhances the effect of preventing the conductive pattern from being attacked during the etching process but decreases a contact open area. Therefore, the etch stop layer is formed with a thin thickness.

Meanwhile, gradual progression in large-scale of integration leads to a decrease in pitch, and an excessive etching is accelerated to a greater extent as a vertical array of each unit device increases. Thus, it becomes difficult to obtain an intended etch profile and simultaneously prevent the conductive pattern from being attacked with the sole application of the etch stop layer having a single nitride layer.

FIGS. 1A to 1D are cross-sectional views of a semiconductor device with a conventional etch stop layer having a structure of nitride layer/oxide layer/nitride layer. With reference to these drawings, a conventional method and problems related to the conventional method will be explained below.

Referring to FIG. 1A, a plurality of gate electrodes G are formed on a substrate 10 providing various elements of a semiconductor device. Each of the gate electrodes G has a stack structure of an insulation layer 11A, a conductive layer 11B and a hard mask 11C. An active region 12 expanded from a surface of the substrate 10 allocated between the gate electrode patterns G is formed.

Herein, the insulation layer 11A is a typical gate insulation layer and is made of an oxide-based material. The conductive layer 11B is called a gate or a gate electrode and can be formed as various structures, e.g., a sole polysilicon structure, a polycide structure including stacked layers of polysilicon and tungsten silicide, a sole tungsten structure, a stack structure of polysilicon and tungsten and a stack structure of tungsten and tungsten silicide. Also, the active region 12, e.g., a source/drain junction, is formed through an ion implantation of p-type or n-type impurities and a thermal expansion.

A bottom nitride layer 13A, an oxide layer 13B and a top nitride layer 13C are deposited with a thin thickness along a profile including the gate electrode patterns G so that an etch stop layer S with a triple layer structure is formed.

Then, a first inter-layer insulation layer 14 of which a top surface is plane is formed on an entire surface of the etch stop layer S such that the first inter-layer insulation layer 14 sufficiently fills a space between the gate electrode patterns G. Herein, the first inter-layer insulation layer 14 uses an oxide-based material. The oxide-based material such as borophosphosilicate glass (BPSG), borosilicate glass (BSG), phosphosilicate glass (PSG), tetraethylorthosilicate (TEOS), high density plasma (HDP) oxide, advanced planarization layer (APL) and an organic or inorganic-based dielectric material with a low dielectric constant (K) is formed in a single layer or stacked layers for forming the first inter-layer insulation layer 14. After depositing the first inter-layer insulation layer 14, a flow process and planarization process are separately performed to make the deposited first inter-layer insulation layer 14 planarized.

Subsequent to the deposition of the first inter-layer insulation layer 14, a photoresist pattern is coated, and a photo-exposure and developing process is performed to form a photoresist pattern 15 for a cell contact. Afterwards, a SAC etching process is performed to form a contact hole (not shown) for the cell contact.

In more detail of the SAC etching process, the first inter-layer insulation layer 14 is etched by using the photoresist pattern 15 as an etch mask. This SAC etching process is denoted as a numeral reference 16 in FIG. 1A. The stack structure of bottom nitride layer 13A/oxide layer 13B/top nitride layer 13B is sequentially etched until the active region 12 is exposed. Thereafter, a cleaning process is performed to secure a contact opening area and remove etch remnants. Herein, such gas containing carbon (C) and fluorine (F), e.g., C₃F₆, C₄F₆, C₄F₈ and C₅F₈, and such gas containing C, H and F, e.g., CHF₃ and CH₂F₂, are mixed together to be used in the SAC etching process. During the above SAC etching process, a partial portion of the oxide layer 13B is inevitably exposed.

Next, a material for forming a plug is deposited along a profile containing the contact hole, and a chemical mechanical polishing (CMP) process is performed to form a plurality of isolated plugs 17. However, it is noted that only the single isolated plug 17 is illustrated in FIG. 1B. Herein, polysilicon, barrier metal and tungsten are examples of the material for forming the plug 17. For the CMP process, corrosive slurry containing a polishing agent is used. At this time, the slurry uses a material containing silicon dioxide (SiO₂) or cerium dioxide (CeO₂). Residues of the used slurry remain after the CMP process.

Therefore, it is necessary to perform an additional cleaning process. At this time, the cleaning solution is diluted fluoric acid (HF) or buffered oxide etchant (BOE).

Meanwhile, the HF-based solution has a high etching ratio with respect to an oxide layer. Thus, during the cleaning process performed after forming the isolated plugs 17, a selective etching of the oxide layer 13B rapidly occurs along narrow interstitial spaces of the oxide layer 13B, which is made of an insulating material with a lower dielectric constant than those of the top and bottom nitride layers 13C and 13A of the etch stop layer S disposed in sidewalls of each gate electrode pattern G. In FIG. 1B, the reference symbol A expresses a partial loss of an upper portion of the oxide layer 13B by the cleaning process.

Referring to FIG. 1C, a second inter-layer insulation layer 18 and a third inter-layer insulation layer 19 are formed on an entire surface of the above resulting structure, and then, a photoresist pattern 20 for forming a storage node contact hole is formed. The third inter-layer insulation layer 19 and the second inter-layer insulation layer 18 are selectively etched by using the photoresist pattern 19 as an etch mask so that a contact hole 21 exposing the predetermined plug 17 is formed.

Herein, the etching process proceeds by adopting the SAC etching process, and this SAC etching process is accelerated at the etched-away lost portion A of the oxide layer 13B. Thus, the conductive layer 11B and the hard mask 11C of the gate electrode pattern G are damaged. This damage is denoted as the reference symbol B. This damage of the gate electrode pattern G causes an electric short circuit between the gate electrode pattern G and a subsequently formed storage node contact plug.

The loss of the oxide layer 13B is more severe at edge areas of a wafer wherein the thickness of the hard mask 11C is relatively thin. Furthermore, in case the etch mask is misaligned, this loss of the oxide layer 13B is pronounced to a greater extent during the formation of the storage node contact hole 21. More specifically, a hole type of the storage node contact hole 21 is more prone to the above loss than a line type.

As one of methods for solving the above mentioned problem, the thickness of the hard mask 11 is increased. However, in this case, the height of the hard mask 11 is also needed to be increased before performing the SAC etching process. This increased height of the hard mask 11C makes it difficult to control a sectional etching surface of the gate electrode. Particularly, compared to a circuit region in which dense patterns are formed, there arise more frequently a difference in critical dimension (CD) obtained before and after the etching process in a region where isolated patterns are formed, e.g., in a peripheral circuit region. This effect is called etch loading effect. Also, the increased thickness of the hard mask increases an aspect ratio, further resulting in a poor gap-filling of a subsequently deposited insulation layer.

In another method for solving the aforementioned problem, it is possible to use a more diluted cleaning solution. However, in this case, the cleaning process is prolonged, thereby decreasing yields of semiconductor devices.

It is also possible to reduce the size of the storage node contact to solve the problem created by the misalignment of the etch mask during the formation of the storage node contact. However, this method is disadvantageous in defective contact opening; in a severe case, the contact opening may not be even formed, and thereby increasing needs of rework.

Referring to FIG. 1D, a conductive material, e.g., doped polysilicon, is deposited along a profile containing the contact hole 21 to form a storage node contact plug 22. Although not illustrated, a plurality of the storage node contact plugs 22 are formed. Then, a CMP process is performed to make the storage node contact plugs 22 isolated from each other.

The losses of the oxide layer 13B and the hard mask 11C results in an electric short circuit between the storage node contact plug 22 and the conductive layer 11B. This electric short circuit is denoted as the reference symbol C in FIG. 1D.

### SUMMARY OF THE INVENTION

It is, therefore, an object of the present invention to provide a method for fabricating a semiconductor device having an attack barrier layer capable of preventing an electric short circuit between a storage node contact plug and a gate electrode by minimizing losses of an intermediate oxide layer of an etch stop layer having a triple layer structure of a bottom nitride layer, the intermediate oxide layer and a top nitride layer during a cleaning process performed after a chemical mechanical polishing process.

In accordance with an aspect of the present invention, there is provided a method for fabricating a semiconductor device, including the steps of: forming an etch stop layer having a multi-layer structure along a profile containing conductive patterns formed on a substrate; etching selectively a first inter-layer insulation layer deposited on the etch stop layer and the etch stop layer to form a first contact hole exposing a surface of the substrate allocated between the conductive patterns; forming a first plug by depositing a conductive layer on an entire surface of the resulting structure containing the first contact hole and planarizing the conductive layer at the same plane level of the conductive patterns and the first inter-layer insulation layer by employing a chemical mechanical polishing (CMP) process; performing a cleaning process to remove remnants from the CMP process; etching selectively a second inter-layer insulation layer deposited along a profile containing the first plug to form a second contact hole exposing the first plug; and forming a second plug electrically connected to the first plug through the second contact hole, wherein an attack barrier layer is formed between the second plug and the conductive pattern.

In accordance with another aspect of the present invention, there is also provided a method for fabricating a semiconductor device, including the steps of: forming an etch stop layer having a multi-layer structure along a profile containing conductive patterns formed on a substrate; etching selectively a first inter-layer insulation layer deposited on the etch stop layer and the etch stop layer to form a first contact hole exposing a surface of the substrate allocated between the conductive patterns; forming a first plug by depositing a conductive layer on an entire surface of a structure containing the first contact hole and planarizing the conductive layer at the same plane level of the conductive patterns and the first inter-layer insulation layer by employing a CMP process; performing a cleaning process to remove remnants from the CMP process; forming an attack barrier layer on an entire surface of the resulting structure including the first plug; etching selectively a second inter-layer insulation layer formed on the attack barrier layer and the attack barrier layer to form a second contact hole exposing the first plug; and forming a second plug electrically connected to the first plug through the second contact hole.

In accordance with still another aspect of the present invention, there is also provided a method for fabricating a semiconductor device, including the steps of: forming an etch stop layer having a multi-layer structure along a profile containing conductive patterns formed on a substrate; etching selectively a first inter-layer insulation layer deposited on the etch stop layer and the etch stop layer to form a first contact hole exposing a surface of the substrate allocated between the conductive patterns; forming a first plug by depositing a conductive layer on an entire surface of a structure containing the first contact hole and planarizing the conductive layer at the same plane level of the conductive patterns and the first inter-layer insulation layer by employing a CMP process; performing a cleaning process to remove remnants from the CMP process; etching selectively a second inter-layer insulation layer deposited on the resulting structure including the first plug to form a second contact hole exposing the first plug; forming an attack barrier layer along a profile containing the second contact hole; removing the attack barrier layer disposed at a bottom surface of the second contact hole through an etch-back process; and forming a second plug electrically connected to the first plug through the second contact hole.

In accordance with another aspect of the present invention, there is provided a method for fabricating a semiconductor device, including the steps of: forming an etch stop layer having a multi-layer structure along a profile containing conductive patterns formed on a substrate; etching selectively a first inter-layer insulation layer deposited on the etch stop layer and the etch stop layer to form a first contact hole exposing a surface of the substrate allocated between the conductive patterns; forming a first plug by depositing a conductive layer on an entire surface of a structure containing the first contact hole and planarizing the conductive layer at the same plane level of the conductive patterns and the first inter-layer insulation layer by employing a CMP process; performing a cleaning process to remove remnants from the CMP process; etching selectively a second inter-layer insulation layer deposited on the first plugs to form a second contact hole exposing the first plug; and forming a second plug electrically connected to the first plug through the second contact hole.

### BRIEF DESCRIPTION OF THE DRAWING(S)

The above and other objects and features of the present invention will become apparent from the following description of the preferred embodiments given in conjunction with the accompanying drawings, in which:

FIGS. 1A to 1D are cross-sectional views of a conventional semiconductor device having an etch stop layer with a triple layer structure of a bottom nitride layer, an intermediate oxide layer and a top nitride layer;

FIGS. 2A to 2D are cross-sectional views of a semiconductor device fabricated in accordance with a first preferred embodiment of the present invention; and

FIGS. 3A to 3E are cross-sectional views of a semiconductor device fabricated in accordance with a second embodiment of the present invention.

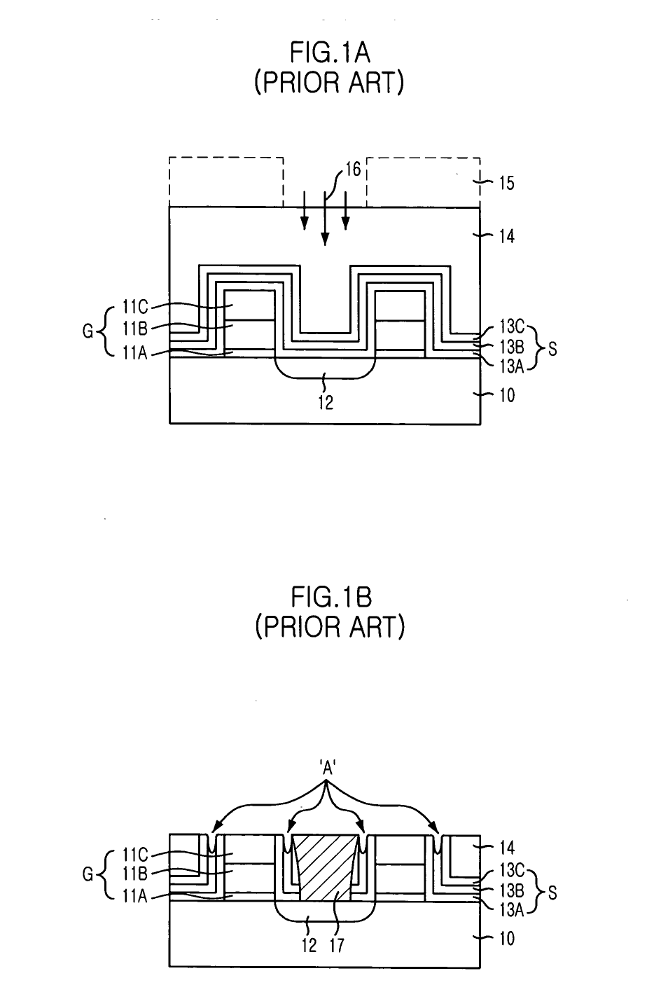

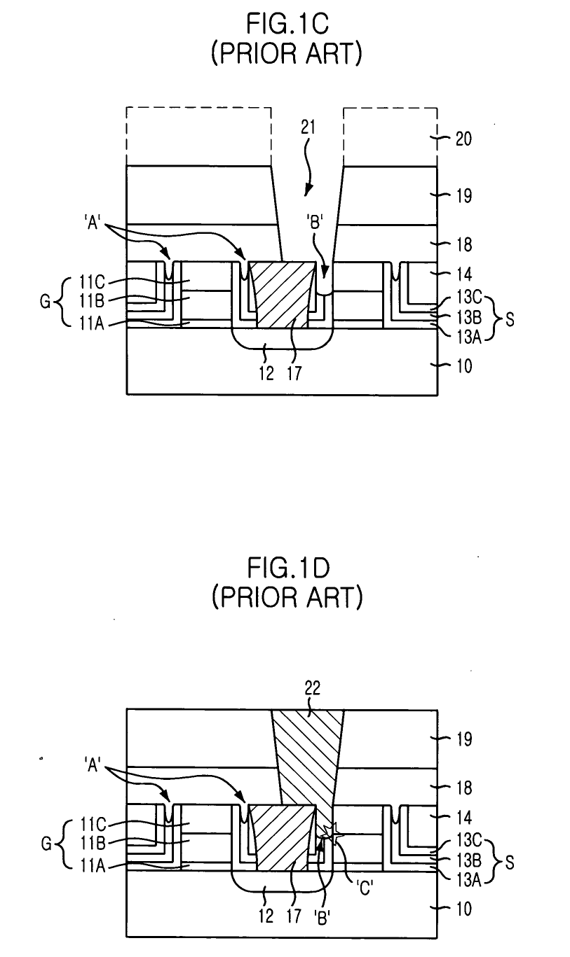

### DETAILED DESCRIPTION OF THE INVENTION

Hereinafter, a method for fabricating a semiconductor device having an etch stop layer with a triple layer structure of a bottom nitride layer, an intermediate oxide layer and a top nitride layer will be described with reference to accompanying drawings.

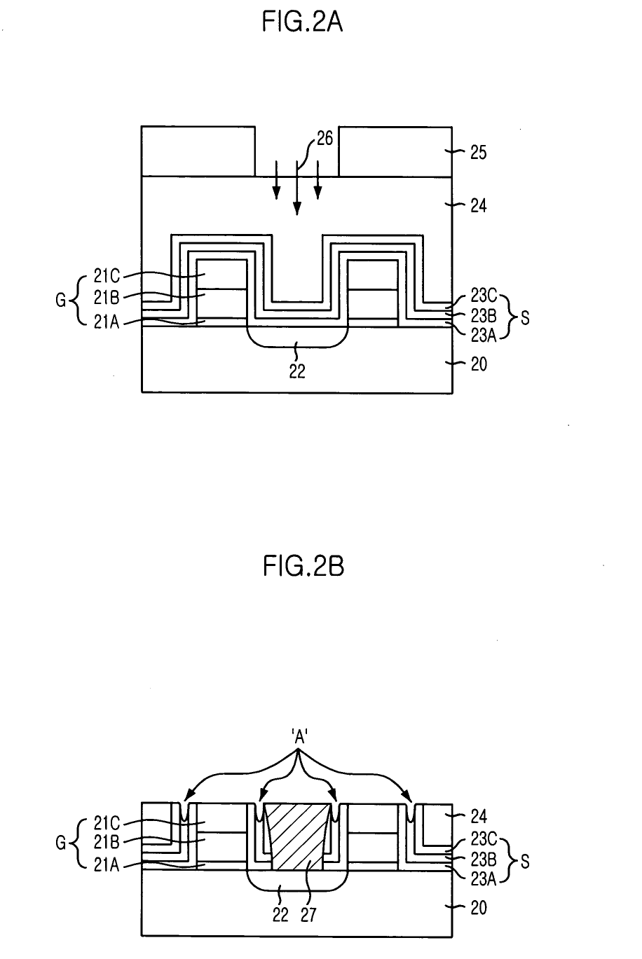

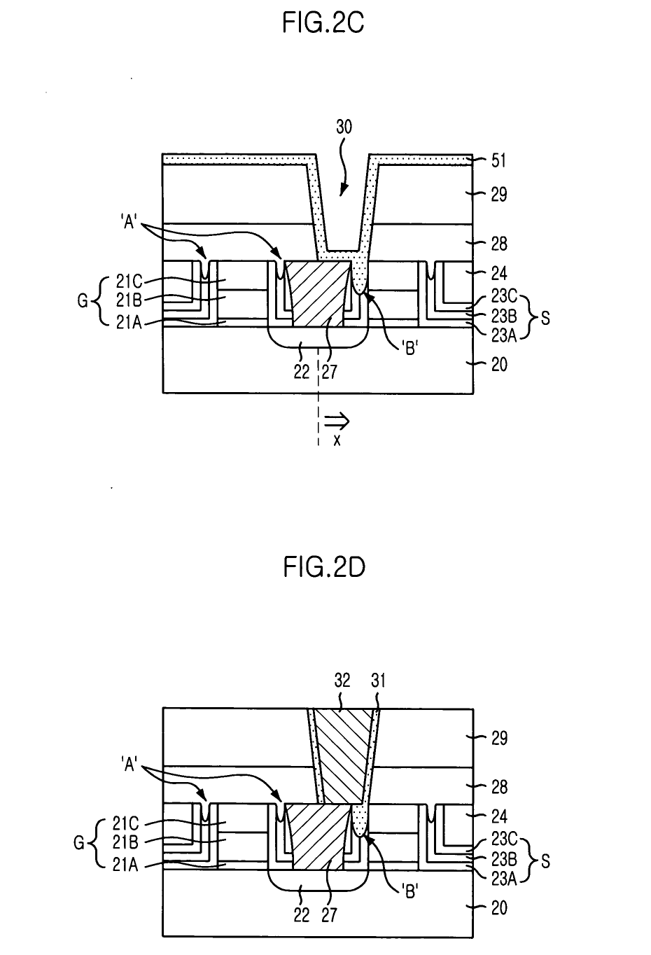

FIGS. 2A to 2D are cross-sectional views of a semiconductor device fabricated in accordance with a first preferred embodiment of the present invention.

Referring to FIG. 2A, a plurality of gate electrodes G having a stack structure of an insulation layer 21A, a conductive layer 21B and a hard mask 21C are formed on a substrate 20 providing various elements of a semiconductor device. An active region 22 expanded from a surface of the substrate 20 allocated between the gate electrode patterns G is formed.

Herein, the insulation layer 21A is a typical gate insulation layer and is made of an oxide-based material. The conductive layer 21B is called a gate or a gate electrode and can be formed in various structures, e.g., a sole polysilicon structure, a polycide structure including stacked layers of polysilicon and tungsten silicide, a sole tungsten structure, a stack structure of polysilicon and tungsten and a stack structure of tungsten and tungsten silicide. Also, the active region 22, e.g., a source/drain junction, is formed through an ion implantation of p-type or n-type impurities and a thermal expansion. In the preferred embodiments of the present invention, the gate electrode pattern is shown as an exemplary conductive pattern among other various types of the conductive pattern.

Next, a bottom nitride layer 23A, an intermediate oxide layer 23B and a top nitride layer 23C are deposited thinly along a profile containing the gate electrode patterns G, so that a triple layer structure of an etch stop layer S is formed.

Although the preferred embodiments of the present invention exemplifies the etch stop layer S with the triple layer structure including the bottom nitride layer 23A, the intermediate oxide layer 23B and the top nitride layer 23C, the etch stop layer S can have other various types of structure including at least more than one insulating material-based layer with a lower dielectric constant K than that of the nitride layers allocated on top and bottom parts of the structure. Herein, the insulating material-based layer used in this preferred embodiment is one of an oxide-based layer, an aluminum oxide (Al₂O₃) and tantalum oxynitride (TaON) layer.

That is, the etch stop layer S can have a multi-layer structure with various combinations of stacked layers including particularly the oxide layer as an intermediate layer disposed between the stacked layers. For instance, the etch stop layer S can have a triple layer structure of nitride layer/oxide layer/nitride layer or nitride layer/Al₂O₃ or TaON layer/nitride layer or a penta layer structure of nitride layer/oxide layer/nitride layer/oxide layer/nitride layer.

Subsequent to the formation of the triple layer structure of the etch stop layer S, a first inter-layer insulation layer 24 of which top surface is plane is formed on an entire surface of the etch stop layer S such that the first etch stop layer 24 is filled into a space between the gate electrode patterns G. At this time, the first inter-layer insulation layer 24 is made of an oxide-based material. The oxide-based material such as borophosphosilicate glass (BPSG), borosilicate glass (BSG), phosphosilicate glass (PSG), tetraethylorthosilicate (TEOS), high density plasma (HDP) oxide, advanced planarized layer (APL), spin on dielectric (SOD), silicate on glass (SOD) and an organic or inorganic-based dielectric material with a low dielectric constant (K) is formed in a single layer or stacked layers for forming the first inter-layer insulation layer 24. Meanwhile, an additional flow process, an annealing process and a planarization process may be performed to densify the above thin layers and planarize an upper surface of the first inter-layer insulation layer 24.

Then, a photoresist is coated on the first inter-layer insulation layer 24 and a photo-exposure and developing process proceeds to form a photoresist pattern 25, which is a mask for forming a cell contact. A self-aligned contact (SAC) etching process is subsequently performed to form a first contact hole (not shown) for forming the cell contact.

In more detail of the SAC etching process, the first inter-layer insulation layer 24 is etched by using the photoresist pattern 25 as an etch mask, and then, the bottom nitride layer 23C, the oxide layer 23B and the top nitride layer 23A are sequentially etched until the active region 22 is exposed. This SAC etching is denoted as the numeral reference 26.

In addition, prior to the SAC etching process for forming the first contact hole, it is also possible to etch a partial portion or an entire portion of the first inter-layer insulation layer 24 and the etch stop layer S disposed on an upper surface of the gate electrode pattern G through a plasma etching process along with use of a mask opening only a cell region. Also, a CMP process can still be used to etch the entire portion of the etch stop layer S and the first inter-layer insulation layer 24 without performing the above mask process. In the case of etching the partial portion of the etch stop layer S and the first inter-layer insulation layer 24 through one of the above mentioned processes, the thickness of the first inter-layer insulation layer 24 and the etch stop layer S disposed on the upper surface of the gate electrode pattern G preferably ranges from about 500 Å to about 1500 Å.

The above described CMP process or plasma etching process both applied prior to the SAC etching process to etch the entire portion of the first inter-layer insulation layer 24 and the etch stop layer S disposed on the gate electrode pattern G provides the effect of a reduced thickness of an etch target to thereby secure a sufficient critical dimension (CD) of the bottom contact and increase margins for the etching process.

Next, a cleaning process is subsequently performed to secure a contact opening area and remove etch remnants. Also, such a gas containing C and F as C₃F₆, C₄F₆, C₄F₈ and C₅F₈ and such a gas containing C, H and F as CH₂F₂ are mixed together to be used in the SAC etching process. At this time of performing the SAC etching process for forming the first contact hole, a partial portion of the oxide layer 23B of the etch stop layer S is inevitably exposed.

Subsequent to the SAC etching process, a material for forming a plug (hereinafter referred to as a plug material) is deposited along a profile containing the first contact hole. Herein, the plug material is polysilicon. A CMP process is performed after the deposition of the plug material so that a plurality of the first plugs 27 isolated from each other are formed. It should be noted that only one of the first plugs 27 is illustrated in FIG. 2B. Herein, the corrosive slurry containing a polishing agent is used for the CMP process. The slurry uses a material containing silicon dioxide SiO₂ or cerium dioxide CeO₂. Residues of the used slurry remain after the CMP process.

Therefore, it is necessary to perform an additional cleaning process after the CMP process. Such solution as diluted hydrofluoric acid (HF) or buffered oxide etchant (BOE) is used as a cleaning solution. Meanwhile, the HF-based solution has a high etch ratio with respect to an oxide layer. Thus, the oxide layer 23B, i.e., the insulating material-based layer except for the top and bottom nitride layers 23C and 23A of the etch stop layer S disposed in sidewalls of each gate electrode pattern G, is selectively etched during the cleaning process performed after forming the isolated first plugs 27. In FIG. 2B, the reference symbol A expresses a partial loss of an upper portion of the oxide layer 23B by the cleaning process.

Referring to FIG. 2C, a second inter-layer insulation layer 28 and a third inter-layer insulation layer 29 are formed on an entire surface of the above resulting structure, and then, a photoresist pattern (not shown) for forming a storage node contact hole is formed. The third inter-layer insulation layer 29 and the second inter-layer insulation layer 28 are selectively etched by using the photoresist pattern as an etch mask, so that a second contact hole 30 exposing a surface of the predetermined first plug 27 is formed. Although a plurality of the second contact holes and the first plugs 27 exist, only the single set of the second contact hole 30 and the predetermined first plug 27 is shown.

As described above, during the SAC etching process for forming the second contact hole 30, the lost portion A of the oxide layer 23B extends to the gate electrode patterns G, particularly to the hard mask 21C and the conductive layer 21B. This extension is denoted as the reference symbol B.

Hence, an attack barrier layer 31 is formed along a profile containing the second contact hole 30 to prevent occurrences of an electric short circuit between a subsequently formed second plug, i.e., a storage node contact plug, and the gate electrode pattern G. Particularly, the attack barrier layer 31 is made of a nitride-based material and has a preferable thickness ranging from abut 30 Å to about 300 Å.

A post etch treatment proceeds prior to a wet cleaning process performed right after the above described SAC etching process in order to partially remove polymeric by-products produced during the SAC etching process. A dry cleaning process employed as the post-etch treatment uses a typical gas of Ar/O₂. The post-etch treatment is preferably continued for less than about 30 seconds to minimize the loss of the etch stop layer S or the hard mask 21C of the gate electrode pattern G.

FIG. 2C shows a case of an incidence of a mask misalignment during the formation of the second contact hole 30. Because of the mask misalignment, the contact mask is shifted to a direction of X from a center region. Hence, such loss expressed as B is more extended, and the lost portion B is filled with the attack barrier layer 31.

Referring to FIG. 2D, an etch-back process is performed to remove an upper portion of the third inter-layer insulation layer 29 and a partial portion of the attack barrier layer 31 disposed at a bottom part of the second contact hole 30. Then, a conductive material for forming a storage node contact plug is deposited along a profile containing the second contact hole 30. Herein, doped polysilicon is an example of the conductive material. Thereafter, a CMP process is performed to form a plurality of the storage node contact plugs 32 isolated from each other. However, as shown, only the single storage node contact plug 32 is illustrated.

After the deposition of the second inter-layer insulation layer 28, a bit line formation process is performed. However, detailed descriptions on the bit line formation process are omitted.

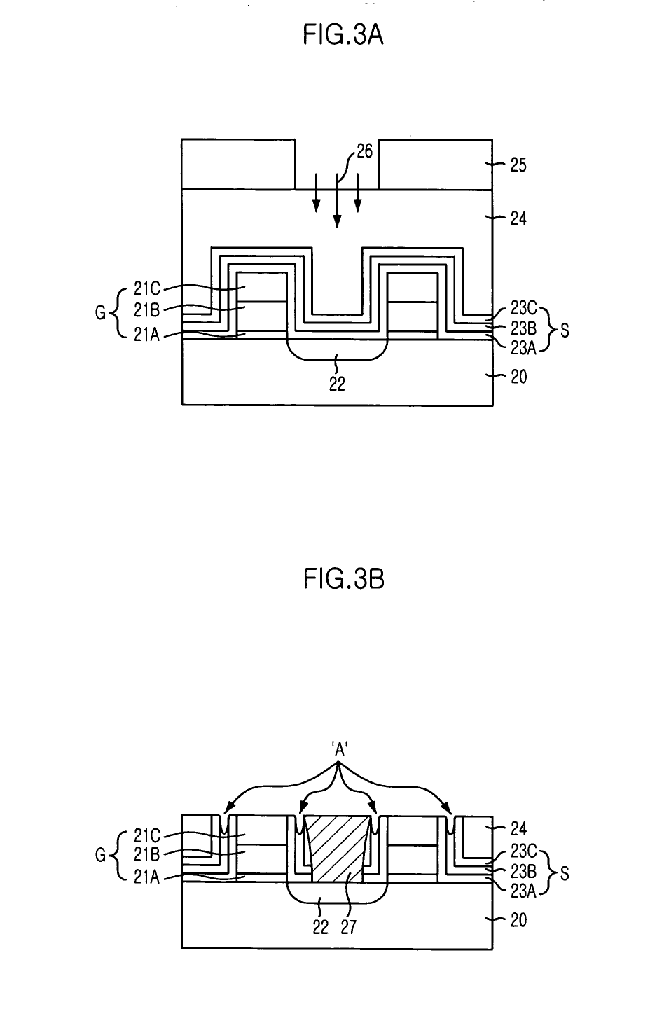

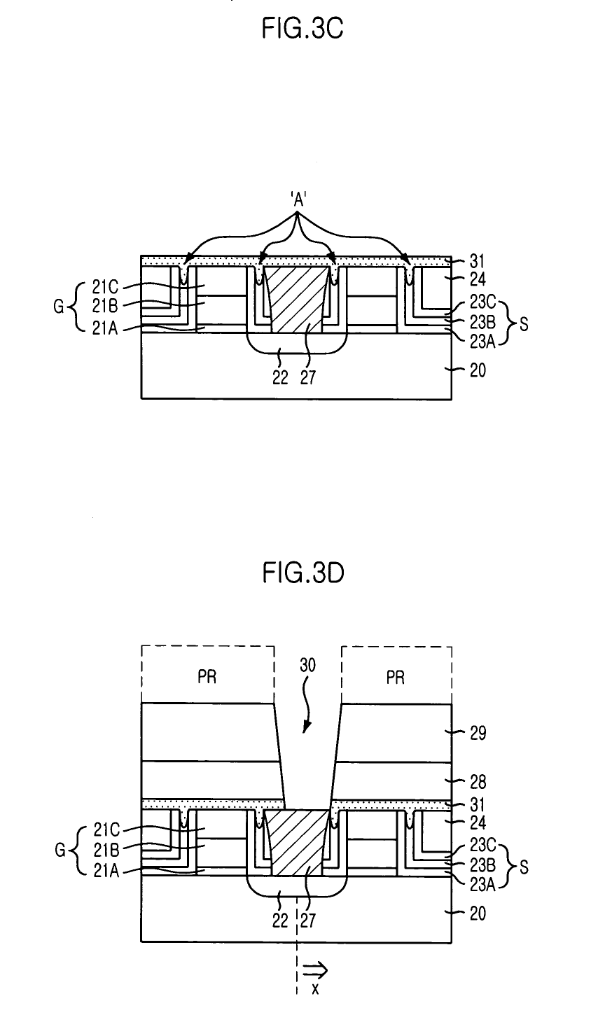

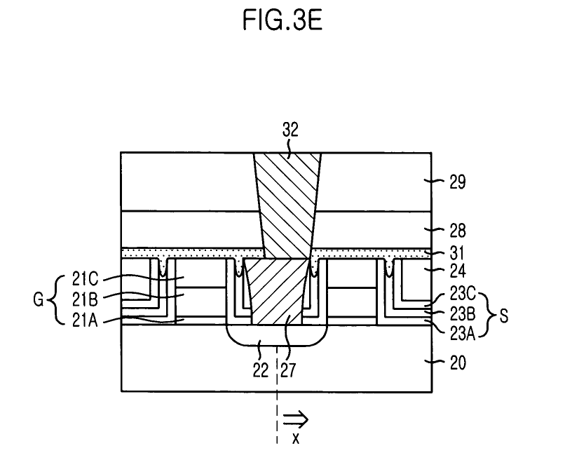

FIGS. 3A to 3E show cross-sectional views of a semiconductor device fabricated in accordance with a second preferred embodiment of the present invention. The same numeral references are used for the identical constitution elements, and detailed descriptions on such elements are omitted.

In the second preferred embodiment, an attack barrier layer 31 is deposited on an entire surface of the resulting structure as shown in FIG. 3B to prevent an electric short circuit between a subsequent second plug 32, i.e., a storage node contact plug, and the gate electrode pattern G. As described above, the electric short circuit occurs when the lost portion A of the oxide layer 23B which occurred during the cleaning process is extended to the gate electrode patterns G during formation of a subsequent second contact hole 30, i.e., a storage node contact hole. Therefore, as shown in FIG. 3C, the attack barrier layer 31 is formed in a manner to be filled into the lost portion A of the oxide layer 23B.

Referring to FIG. 3D, a second inter-layer insulation layer 28 and a third inter-layer insulation layer 29 are formed on the resulting structure containing the attack barrier layer 31. Then, a photoresist pattern PR for forming the storage node contact hole is formed. The photoresist pattern PR is used as an etch mask when the third inter-layer insulation layer 29, the second inter-layer insulation layer 28 and the attack barrier layer 31 are selectively etched to form a second contact hole 30 exposing the first plug 27. Although not illustrated, there is a plurality of the second contact holes 30.

Meanwhile, the attack layer 31 prevents the lost portion A of the oxide layer 23B from being extended to the gate electrode patterns G, particularly, to the hard mask 21C and the conductive layer 21B during the SAC etching process for forming the second contact hole 30.

Also, the lost portion A is not extended towards bottom parts of the constructed structure due to the attack barrier layer 31 even if a mask misalignment, which causes the contact mask to be shifted to a direction of X from a central region, occurs during the second contact hole 30 formation process.

Referring to FIG. 3E, a conductive material for forming a storage node contact plug is deposited on an entire surface of the structure including the second contact hole 30. Herein, doped polysilicon is an example of the conductive material. After the deposition of the conductive material, isolated storage node contact plugs 32 are formed by performing a CMP process. It should be noted that only one of the storage node contact plugs 32 are shown in FIG. 3E although a plurality of the storage node contact plugs 32 are formed.

After the deposition of the second inter-layer insulation layer 28, a bit line formation process is performed, and detailed descriptions on this bit line formation process are omitted.

In addition to the use of the attack barrier layer 31, it is possible to alternatively use an insulating material-based thin layer having a flow-fill property of filling the exposed portion of the oxide layer 23B disposed at sidewalls of the conductive patterns G. At this time, the insulating material-based thin layer is made of an oxide-based material selected from a group consisting of advanced planarization layer (APL), spin on dielectric (SOD), spin on glass (SOG) and borophosphosilicate glass (BPSG). Also, the insulating material-based thin layer has a thickness ranging from about 1000 Å to about 8000 Å.

As seen from the first and the second preferred embodiments of the present invention, the CMP process is performed to form the first plug in between the conductive patterns, e.g., gate electrode patterns, with the etch stop layer having the nitride layers as the top and bottom layers and the intermediate insulation layer, e.g., the oxide layer, having a lower dielectric constant than those of the nitride layers. However, in the course of removing remnants generated from the CMP process by employing the cleaning process, the oxide layer of which a partial portion is inevitably exposed during the formation of the first contact hole is partially lost due to its higher etch ratio than the nitride layer. This partial loss of the oxide layer becomes more severe during the SAC etching process for forming the second plug, e.g., storage node contact plug. This fact further results in a poor quality of a semiconductor device due to frequent occurrences of electric short circuit between the conductive pattern and the second plug. This problem is solved in the above first and the second preferred embodiment of the present invention by forming the attack barrier layer between the conductive pattern and the second plug.

Particularly, in the first preferred embodiment, the attack barrier layer is deposited after the CMP process for forming the first plug and the cleaning process such that the attack barrier layer is filled into the lost portion of the insulating material-based layer, i.e. the oxide layer. As a result of the use of this attack barrier layer, it is possible to prevent the lost portion being extended to the bottom parts of the conductive patterns in the course of forming the second plug.

In the second preferred embodiment, after the formation of the first contact hole, the attack barrier layer is deposited down to the lost portions of the conductive patterns along the damaged insulating material-based layer, i.e. the oxide layer. Then, the first plug is exposed by performing the etch-back process, and the second plug is formed thereafter. As a result, it is possible to prevent the incidence of electric short circuit between the conductive pattern and the second plug.

In addition to the first and the second preferred embodiments, the insulating material-based thin layer having a flow-fill property of filling the lost portion of the oxide layer serves as the function of the attack barrier layer.

As an ultimate result of employing the above described preferred embodiments, it is possible to increase yields of semiconductor devices.

While the present invention has been described with respect to certain preferred embodiments, it will be apparent to those skilled in the art that various changes and modifications may be made without departing from the scope of the invention as defined in the following claims.

What is claimed is:

1. A method for fabricating a semiconductor device, comprising the steps of:
forming an etch stop layer having a multi-layer structure along a profile containing conductive patterns formed on a substrate;
etching selectively a first inter-layer insulation layer deposited on the etch stop layer and the etch stop layer to form a first contact hole exposing a surface of the substrate allocated between the conductive patterns;
forming a first plug by depositing a conductive layer on an entire surface of the resulting structure containing the first contact hole and planarizing the conductive layer at the same plane level of the conductive patterns and the first inter-layer insulation layer by employing a chemical mechanical polishing (CMP) process;
performing a cleaning process to remove remnants from the CMP process;
etching selectively a second inter-layer insulation layer deposited along a profile containing the first plug to form a second contact hole exposing the first plug; and
forming a second plug electrically connected to the first plug through the second contact hole, wherein an attack barrier layer is formed between the second plug and the conductive pattern.

2. The method as recited in claim 1, wherein the multi-layer structure of the etch stop layer includes nitride layers as top and bottom most layers and at least one insulating material-based layer being disposed between the nitride layers -and having a lower dielectric constant than those of the nitride layers

3. The method as recited in claim 1, further comprising the step of etching a partial portion or an entire portion of the first inter-layer insulation layer and the etch stop layer disposed on an upper surface of each conductive pattern by performing one of a plasma etching process with use of a mask opening only a cell region and a CMP process prior to the step of performing the SAC etching process for forming the first contact hole.

4. The method as recited in claim 3, wherein in etching the partial portion of the first inter-layer insulation layer and the etch stop layer disposed on each conductive pattern, the thickness of the first inter-layer insulation layer and the etch stop layer disposed on each conductive pattern ranges from about 500 Å to about 1500 Å.

5. The method as recited in claim 1, wherein after the step of performing the cleaning process, the attack barrier layer is deposited on an entire surface of the profile containing the first plug.

6. The method as recited in claim 1, wherein after the step of forming the second contact hole, the attack barrier layer is formed along a profile containing the second contact hole.

7. The method as recited in claim 1, wherein the attack barrier layer is a nitride-based layer.

8. The method as recited in claim 1, wherein the attack barrier layer has a thickness ranging from about 50 Å to about 500 Å.

9. The method as recited in claim 2, wherein the insulating material-based layer having a lower dielectric constant than those of the nitride layers uses one of an oxide-based layer, an aluminum oxide (A1₂O₃) layer and a tantalum oxynitride (TaON) layer.

10. The method as recited in claim 1, wherein the cleaning process uses a cleaning solution of hydrofluoric acid (HF) or buffered oxide etchant (BOE).

11. The method as recited in claim 1, wherein the conductive pattern is a gate electrode pattern and the second plug is a storage node contact plug.

12. A method for fabricating a semiconductor device, comprising the steps of:
forming an etch stop layer having a multi-layer structure along a profile containing conductive patterns formed on a substrate;
etching selectively a first inter-layer insulation layer deposited on the etch stop layer and the etch stop layer to form a first contact hole exposing a surface of the substrate allocated between the conductive patterns;
forming a first plug by depositing a conductive layer on an entire surface of a structure containing the first contact hole and planarizing the conductive layer at the same plane level of the conductive patterns and the first inter-layer insulation layer by employing a CMP process;
performing a cleaning process to remove remnants from the CMP process;
forming an attack barrier layer on an entire surface of the resulting structure including the first plug;
etching selectively a second inter-layer insulation layer formed on the attack barrier layer and the attack barrier layer to form a second contact hole exposing the first plug; and
forming a second plug electrically connected to the first plug through the second contact hole.

13. The method as recited in claim 12, wherein the multi-layer structure of the etch stop layer includes nitride layers as top and bottom most layers and at least one insulating material-based layer being disposed between the nitride layers and having a lower dielectric constant than those of the nitride layers.

14. The method as recited in claim 12, further comprising the step of etching a partial portion or an entire portion of the first inter-layer insulation layer and the etch stop layer disposed on an upper surface of each conductive pattern by performing one of a plasma etching process with use of a mask opening only a cell region and a CMP process prior to the step of performing the SAC etching process for forming the first contact hole.

15. The method as recited in claim 14, wherein in case of etching the partial portion of the first inter-layer insulation layer and the etch stop layer disposed on each conductive pattern, the thickness of the first inter-layer insulation layer and the etch stop layer disposed on each conductive pattern preferably ranges from about 500 Å to about 1500 Å.

16. The method as recited in claim 12, wherein the attack barrier layer is a nitride-based layer.

17. The method as recited in claim 12, wherein the attack barrier layer has a thickness ranging from about 50 Å to about 500 Å.

18. The method as recited in claim 13, wherein the insulating material-based layer having a lower dielectric constant than those of the nitride layers uses one of an oxide-based layer, an A1₂O₃ layer and a TaON layer.

19. The method as recited in claim 12, wherein the cleaning process uses a cleaning solution of HF or BOE.

20. The method as recited in claim 12, wherein the conductive pattern is a gate electrode pattern and the second plug is a storage node contact plug.

21. A method for fabricating a semiconductor device, comprising the steps of:
forming an etch stop layer having a multi-layer structure along a profile containing conductive patterns formed on a substrate;
etching selectively a first inter-layer insulation layer deposited on the etch stop layer and the etch stop layer to form a first contact hole exposing a surface of the substrate allocated between the conductive patterns;
forming a first plug by depositing a conductive layer on an entire surface of a structure containing the first contact hole and planarizing the conductive layer at the same plane level of the conductive patterns and the first inter-layer insulation layer by employing a CMP process;
performing a cleaning process to remove remnants from the CMP process;
etching selectively a second inter-layer insulation layer deposited on the resulting structure including the first plug to form a second contact hole exposing the first plug;
forming an attack barrier layer along a profile containing the second contact hole;
removing the attack barrier layer disposed at a bottom surface of the second contact hole through an etch-back process; and
forming a second plug electrically connected to the first plug through the second contact hole.

22. The method as recited in claim 21, wherein the multi-layer structure of the etch stop layer includes nitride layers as top and bottom most layers and at least one insulating material-based layer being disposed between the nitride layers and having a lower dielectric constant than those of the nitride layers.

23. The method as recited in claim 21, further comprising the step of etching a partial portion or an entire portion of the first inter-layer insulation layer and the etch stop layer disposed on an upper surface of each conductive pattern by performing one of a plasma etching process with use of a mask opening only a cell region and a CMP process prior to the step of performing the SAC etching process for forming the first contact hole.

24. The method as recited in claim 23, wherein in case of etching the partial portion of the first inter-layer insulation layer and the etch stop layer disposed on each conductive pattern, the thickness of the first inter-layer insulation layer and the etch stop layer disposed on each conductive pattern preferably ranges from about 500 Å to about 1500 Å.

25. The method as recited in claim 21, wherein the attack barrier layer is a nitride-based layer.

26. The method as recited in claim 21, wherein the attack barrier layer has a thickness ranging from about 50 Å to about 500 Å.

27. The method as recited in claim 22, wherein the insulating material-based layer having a lower dielectric constant than those of the nitride layers uses one of an oxide-based layer, an A1₂O₃ layer and a TaON layer.

28. The method as recited in claim 21, wherein the cleaning process uses a cleaning solution of HF or BOE.

29. The method as recited in claim 21, wherein the conductive pattern is a gate electrode pattern and the second plug is a storage node contact plug.

30. A method for fabricating a semiconductor device,
comprising the steps of:
forming an etch stop layer having a multi-layer structure along a profile containing conductive patterns formed on a substrate;
etching selectively a first inter-layer insulation layer deposited on the etch stop layer and the etch stop layer to form a first contact hole exposing a surface of the substrate allocated between the conductive patterns;
forming a first plug by depositing a conductive layer on an entire surface of a structure containing the first contact hole and planarizing the conductive layer at the same plane level of the conductive patterns and the first inter-layer insulation layer by employing a CMP process;
performing a cleaning process to remove remnants from the CMP process;
etching selectively a second inter-layer insulation layer deposited on the first plugs to form a second contact hole exposing the first plug; and
forming a second plug electrically connected to the first plug through the second contact hole.

31. The method as recited in claim 30, wherein the second inter-layer insulation layer has a flow-fill property.

32. The method as recited in claim 31, wherein the second inter-layer insulation layer is made of an oxide-based material selected from a group consisting of advanced planarization layer (APL), spin on dielectric (SOD), spin on glass (SOG) and borophosphosilicate glass (BPSG).

33. The method as recited in claim 30, wherein the multi-layer structure of the etch stop layer includes nitride layers as top and bottom most layers and at least one insulating material-based layer being disposed between the nitride layers and having a lower dielectric constant than those of the nitride layers.

34. The method as recited in claim 30, further comprising the step of performing a partial portion or an entire portion of the first inter-layer insulation layer and the etch stop layer disposed on an upper surface of each conductive pattern by performing one of a plasma etching process with use of a mask opening only a cell region and a CMP process prior to the step of performing the SAC etching process for forming the first contact hole.

35. The method as recited in claim 34, wherein in case of etching the partial portion of the first inter-layer insulation layer and the etch stop layer disposed on each conductive pattern, the thickness of the first inter-layer insulation layer and the etch stop layer disposed on each conductive pattern ranges from about 500 Å to about 1500 Å.

36. The method as recited in claim 31, wherein the second inter-layer insulation layer has a thickness ranging from about 1000 Å to about 8000 Å.

37. The method as recited in claim 30, wherein the cleaning process proceeds by using one of HF and BOE.

38. The method as recited in claim 30, wherein the conductive pattern is a gate electrode pattern and the second plug is a storage node contact plug.

39. The method as recited in claim 33, wherein the insulating material-based layer having a lower dielectric constant than those of the nitride layers uses one of an oxide-based layer, an A1₂O₃ layer and a TaON layer.
